(19) United States
(12) Patent Application Publication
(10) Pub. No.: US 2010/0127898 A1
(43) Pub. Date: May 27, 2010

(54) INPUT APPARATUS, INPUT METHOD AND ELECTRONIC APPARATUS USING THE SAME

(75) Inventors: Kuan-Yu Chen, Taipei (TW); Hsien-Yang Chiang, Taipei (TW); Yan-Chi Lin, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: E-TEN INFORMATION SYSTEMS CO.,LTD, Taipei (TW)

(21) Appl. No.: 12/394,052

(22) Filed: Feb. 27, 2009

(30) Foreign Application Priority Data
Nov. 26, 2008 (TW) 97145790

(51) Int. Cl. H03M 11/00

(52) U.S. Cl. 341/22

(57) ABSTRACT

An input apparatus, an input method and an electronic apparatus are provided. The input apparatus includes a signal generating module and a processing module. The signal generating module generates a plurality of input signals by executing multi-direction operations. The processing module receives two signals of the input signals which are successively generated by the signal generating module, thus generating a control signal. The control signal corresponds to one of a plurality of characters. Therefore, the input apparatus can be more conveniently used by users to input characters by executing multi-direction operations.

### CROSS-REFERENCE TO RELATED APPLICATION

This application claims the priority benefit of Taiwan application serial no. 97145790, filed on Nov. 26, 2008. The entirety of the above-mentioned patent application is hereby incorporated by reference herein and made a part of specification.

### BACKGROUND OF THE INVENTION

1. Field of the Invention

The present invention generally relates to an input apparatus, an input method and an electronic apparatus using the same, and more particularly, to an electronic apparatus, adapted for inputting characters by executing multi-direction operations.

2. Description of Related Art

As science and technology being fast developed, people now rely more upon portable electronic apparatuses than ever before. Mobile phones, personal digital assistants (PDA), and hand-held game consoles are very popular in people's daily life. Generally, an input interface is an important bridge for communicating between a user and an electronic apparatus. For example, a mobile phone is often provided with an interface including a directional key, numeral keys and function keys, by which the user is allowed to select a function, dial a call, or key in a short message. However, such a keyboard type input interface usually occupies too large an area, and thus restricts the electronic apparatus to be developed to be smaller and lighter.

Therefore, the manufacturers are making more effort to further develop and improve the input method of the electronic apparatus, and reduce the weight and size of the electronic apparatus, for providing more convenience of operation and better portability to the user.

### SUMMARY OF THE INVENTION

Accordingly, the present invention is directed to provide an input apparatus and an input method, adapted for inputting characters by executing multi-direction operations, thus improving the convenience of operation of the input apparatus and reducing the size of the input apparatus. Further, the present invention also provides an electronic apparatus using the input apparatus, and having the foregoing advantages.

The present invention provides an input apparatus. The input apparatus includes a signal generating module and a processing module. The signal generating module generates a plurality of input signals by executing multi-direction operations. The processing module receives and processes successive two of the input signals generated by the signal generating module for generating a control signal. The control signal corresponds to one of a plurality of characters.

The present invention provides an input method, adapted for an electronic apparatus. First, a signal generating module is provided. The signal generating module generates a plurality of input signals by executing multi-direction operations. Then, successively generated two of the input signals are processed for generating a first signal. The first signal corresponds to one of a plurality of characters.

The present invention provides an electronic apparatus including an input apparatus and a display apparatus. The input apparatus includes a signal generating module and a processing module. The signal generating module generates a plurality of input signals by executing multi-direction operations. The processing module receives and processes two of the input signals which are successively generated by the signal generating module for generating a control signal. The control signal corresponds to one of a plurality of characters. The display apparatus receives the control signal and displays the character.

According to an embodiment of the present invention, the signal generating module includes a first, a second, a third, and a fourth input keys. The first input key indicates a first direction, and generates a first input signal of the plurality of input signals when receiving a first operation instruction. The second input key indicates a second direction, and generates a second input signal of the plurality of input signals when receiving a second operation instruction. The third input key indicates a third direction, and generates a third input signal of the plurality of input signals when receiving a third operation instruction. The fourth input key indicates a fourth direction, and generates a fourth input signal of the plurality of input signals when receiving a fourth operation instruction.

According to an embodiment of the present invention, the signal generating module includes a multi-direction key. The multi-direction key indicates a first direction, a second direction, a third direction, and a fourth direction. When receiving the first operation instruction, the second operation instruction, the third operation instruction, and the fourth operation instruction, the multi-direction key generates the first input signal, the second input signal, third input signal, and the fourth input signal of the foregoing input signals, respectively.

The present invention executes multi-direction operations and successively generates input signals. The successively generated input signals are processed for generating a control signal corresponding to one of a plurality of characters. Therefore, the input apparatus is provided with a direction-indicating key for inputting characters by executing multi-direction operations. In such a way, unnecessary keys can be simplified from the input apparatus, and therefore sizes of the input apparatus and the electronic apparatus using the input apparatus can be further reduced, and thus the convenience of operation of the input apparatus is further improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic block diagram illustrating an input apparatus according to an embodiment of the present invention.

FIG. 2A is a schematic diagram illustrating an arrangement of Arabic numerals 0 through 9, according to an embodiment of the present invention.

FIG. 2B is a table illustrating multi-direction operations of inputting the Arabic numerals 0 through 9 according to the embodiment of FIG. 2A.

FIG. 2C is a schematic diagram illustrating an arrangement of English letters A through Z, according to an embodiment of the present invention.

FIG. 2D is a table illustrating multi-direction operations of inputting the English letters A through Z according to the embodiment of FIG. 2C.

FIG. 2E is a schematic diagram illustrating an arrangement of Arabic numerals 0 through 9, according to an embodiment of the present invention.

FIG. 2F is a table illustrating multi-direction operations of inputting the Arabic numerals 0 through 9 according to the embodiment of FIG. 2E.

FIG. 3 is a schematic block diagram illustrating an input apparatus according to another embodiment of the present invention.

FIG. 4 is a flow chart illustrating an input method according to an embodiment of the present invention.

FIG. 5 is a schematic diagram illustrating an electronic apparatus according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

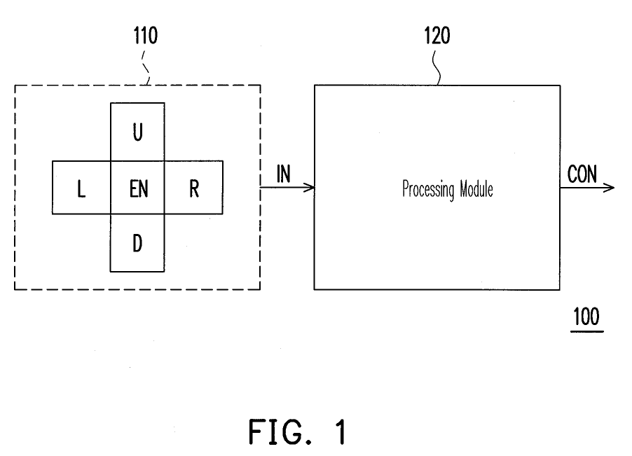

FIG. 1 is a schematic block diagram illustrating an input apparatus according to an embodiment of the present invention. Referring to FIG. 1, an input apparatus 100 includes a signal generating module 110, and a processing module 120. The signal generating module 110 includes a plurality of input keys U, D, L, R, and EN. The input keys U, D, L, and R indicate different directions, respectively, e.g., Up, Down, Left and Right directions. The input key EN is provided for controlling the processing module 120 to execute the processing or terminate the processing.

When the input key U receives a first operation instruction (e.g., the user presses the input key U), the input key U generates a first input signal IN_U, and provides the first input signal IN_U to the processing module 120. When the input key D receives a second operation instruction (e.g., the user presses the input key D), the input key D generates a second input signal IN_D, and provides the second input signal IN_D to the processing module 120. Similarly, when receiving a third and a fourth operation instructions, the input keys L and R generate a third input signal IN_L and a fourth input signal IN_R, and provide the third input signal IN_L and the fourth input signal IN_R to the processing module 120, respectively. The signal generating module 110 generate the first input signal IN_U, the second input signal IN_D, the third input signal, IN_L, and the fourth input signal IN_R by executing multi-direction operations. The processing module 120 receives successive two of the input signals for processing, thus generating a control signal CON corresponding to one of a plurality of characters. The characters for example are Arabic numerals 0 through 9, or English letters A through Z.

Generally, in a conventional keyboard type input apparatus, keys representing Arabic numerals 0 through 9, or English letters A through Z, are often directionally arranged. In the current embodiment, the characters are inputted by executing multi-direction operations according to the directional arrangement of the characters. Specifically, in the current embodiment, not all of the input keys corresponding to the characters are required in the signal generating module 110 corresponding to the characters. The signal generating module 110 is adapted for inputting the characters by operating the input keys U, D, L, and R indicating the Up, Down, Left and Right directions.

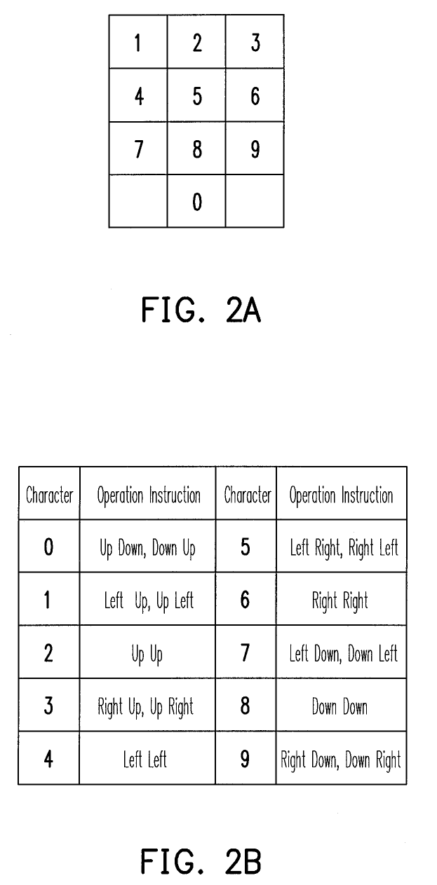

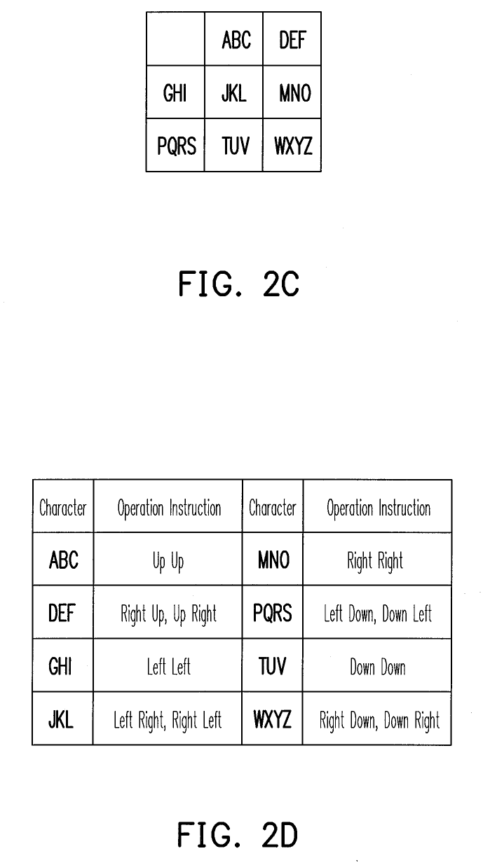

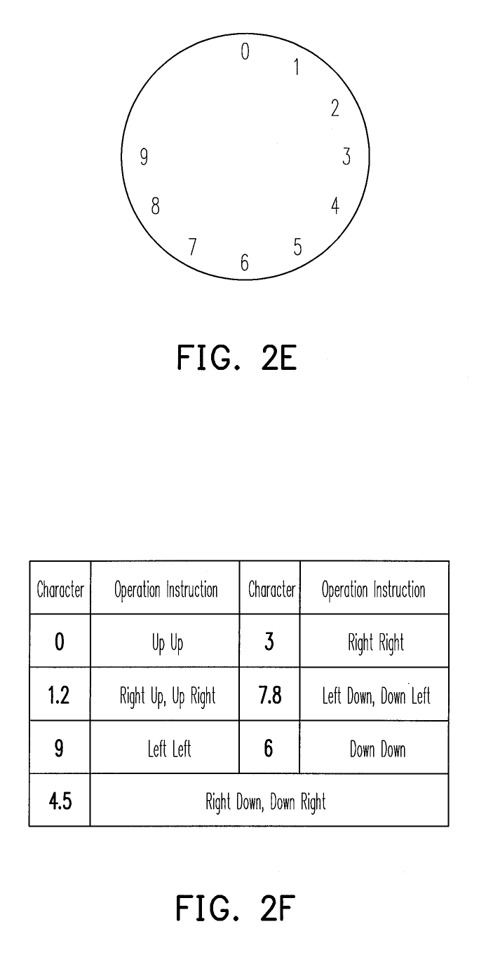

FIG. 2A is a schematic diagram illustrating an arrangement of Arabic numerals 0 through 9, according to an embodiment of the present invention. FIG. 2B is a table illustrating multi-direction operations of inputting the Arabic numerals 0 through 9 according to the embodiment of FIG. 2A. Referring to FIGS. 2A and 2B, taking the Arabic numeral 1 for example, the Arabic numeral 1 is arranged at an upper left side of the Arabic numeral 5. As such, when the signal generating module 110 sequentially receives operation instructions indicating Left and Up directions (or sequentially receives operation instructions indicating Up and Left directions), the processing module 120 processes the third input signal IN_L and the first input signal IN_U which are successively generated by the signal generating module 110, thus generating a control signal CON corresponding to the Arabic numeral 1. Similarly, taking the Arabic numeral 2 for example, when the signal generating module 110 sequentially receives two successive operation instructions indicating the Up direction, the processing module 120 processes the two first input signals IN_U successively generated by the signal generating module 110, thus generating a control signal CON corresponding to the Arabic numeral 2.

Further, in the current embodiment, when the input key EN receives a fifth operation instruction, (e.g., the user presses the input key EN), the signal generating module 110 generates a fifth input signal IN_EN and provides the fifth input signal IN_EN to the processing module 120, for controlling the processing module 120 to execute the processing or terminate the processing. However, it should be noted that the input key EN is not necessarily required hereby. The input key EN is employed in the current embodiment for affirming the correctness of the inputted characters by controlling the processing module 120 to executes the processing or terminates the processing.

Specifically, the signal generating module 110 generates directional input signals (i.e., IN_U, IN_D, IN_L, or IN_R) by executing multi-direction operations. When the processing module 120 receives two successively generated directional input signals, the processing module 120 does not execute the processing until the fifth input signal IN_EN is received. When the processing module 120 receives the fifth input signal IN_EN, it generates the control signal CON. Otherwise, if the processing module 120 fails to receive the fifth input signal IN_EN, it terminates the processing. According to another embodiment of the present invention, when the processing module 120 receives one of the directional input signals, and subsequently receives the fifth input signal IN_EN, the processing module 120 terminates the processing, for avoiding the user inputting an undesired character caused by misoperation of the keys.

FIG. 2C is a schematic diagram illustrating an arrangement of English letters A through Z, according to an embodiment of the present invention. FIG. 2D is a table illustrating multi-direction operations of inputting the English letters A through Z according to the embodiment of FIG. 2C. Referring to FIGS. 2C and 2D, the English letters A through Z are divided into a plurality of letter groups, e.g., letters “ABC”, letters “DEF”, letters “GHI”, letters “JKL”, letters “MNO”, letters “PQRS”, letters “TUV”, letters “WXYZ”. Taking the English letter D for example, the English letter group “DEF” is arranged at an upper right side of the English letter group “JKL”. As such, when the signal generating module 110 sequentially receives operation instructions indicating Right and Up directions (or sequentially receives operation instructions indicating Up and Right directions), the processing module 120 processes the fourth input signal IN_R and the first input signal IN_U which are successively generated by the signal generating module 110, thus generating the control signal CON corresponding to the English letter D.

Then, in accordance with the time of pressing the input key EN, the processing module 120 can be controlled for circularly switching the characters and outputting the control signal CON. For example, when the user shortly presses the input key EN, the signal generating module 110 generates the fifth input signal IN_EN and provides the fifth input signal IN_EN to the processing module 120 for controlling the processing module 120 to switch the control signals CON of the English letters, i.e., switching from the English letter D to the English letter E. Similarly, the user can also control the processing module 120 for circularly switching between the English letters (e.g., from D to E to F to D), by successively and shortly pressing the input key EN. When the user keeps pressing the input key EN (pressing the input key and remaining the input key unreleased for a long time), the processing module 120 outputs the control signal CON corresponding to the English letter.

FIG. 2E is a schematic diagram illustrating an arrangement of Arabic numerals 0 through 9, according to an embodiment of the present invention. FIG. 2F is a table illustrating multi-direction operations of inputting the Arabic numerals 0 through 9 according to the embodiment of FIG. 2E. Referring to FIGS. 2E and 2F, Arabic numerals 0 through 9 are arranged as a layout of a dial plate. The Arabic numerals 0 through 9 can be divided into a plurality of numeral groups, e.g., numeral 0, numerals 1 and 2, numeral 3, numerals 4 and 5, numeral 6, numerals 7 and 8, and numeral 9. Taking the numeral 3 for example, when the signal generating module receives two successively generated operation instructions indicating Right direction, the processing module 120 processes two fourth input signals IN_R successively generated by the signal generating module 110, thus generating a control signal CON corresponding to the Arabic numeral 3.

Further, taking the Arabic numeral 2 for example, the numeral group of numerals 1 and 2 are arranged between the numerals 0 and 3. As such, when the signal generating module 110 sequentially receives operation instructions indicating Right and Up directions (or sequentially receives operation instructions indicating Up and Right directions), the processing module 120 processes a fourth input signal IN_R and a first input signal IN_U which are successively generated by the signal generating module 110, thus generating a control signal CON corresponding to the Arabic numeral 1.

Then, in accordance with the time of pressing the input key EN, the processing module 120 can be controlled for circularly switching the numerals and outputting the control signal CON. For example, when the user shortly presses the input key EN, the signal generating module 110 generates the fifth input signal IN_EN and provides the fifth input signal IN_EN to the processing module 120 for controlling the processing module 120 to switch the control signals CON of the Arabic numerals, i.e., switching from the Arabic numeral 1 to the Arabic numeral 2. Similarly, the user can also control the processing module 120 for circularly switching between the Arabic numerals (e.g., from 1 to 2 to 1), by successively and shortly pressing the input key EN. When the user keeps pressing the input key EN (pressing the input key and remaining the input key unreleased for a long time), the processing module 120 outputs the control signal CON corresponding to the Arabic numerals.

The configuration of the input apparatus and the input keys, as well as the arrangement of the Arabic numerals and the English letters can be complied with many variations. It should be noted that the configurations shown in FIGS. 2A through 2F are provided for illustration only without restricting the scope of the present invention.

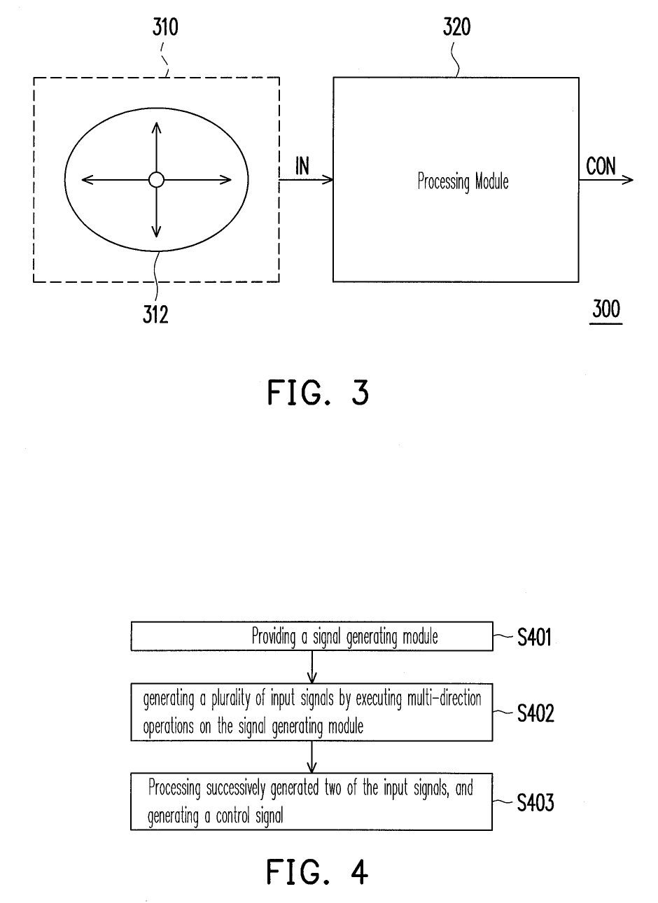

FIG. 3 is a schematic block diagram illustrating an input apparatus according to another embodiment of the present invention. Referring to FIG. 3, an input apparatus 300 is similar with the embodiment of FIG. 1, except that a signal generating module 310 of the input apparatus 300 includes a multi-direction key 312. The multi-direction key 312 for example is a five-direction key, a nine-direction key, a joystick, or a jog key. The signal generating module 310 can be operated in a manner similar with the signal generating module 110 of FIG. 1, in that the input signals are generated by multi-direction operations.

According to the foregoing embodiments, a flow of an input method can be concluded. FIG. 4 is a flow chart illustrating an input method according to an embodiment of the present invention. Referring to FIGS. 1 and 4, first at step S401, the signal generating module 110 is provided, the signal generating module 110 is adapted for generating input signals by executing multi-direction operations. Then, at step S402, when receiving directional operation instructions, the signal generating module 110 generates input signals corresponding to the received directional operation instruction, respectively. At step S403, the processing module 120 processes two successively generated input signals, and generates a control signal CON corresponding to one of a plurality of characters.

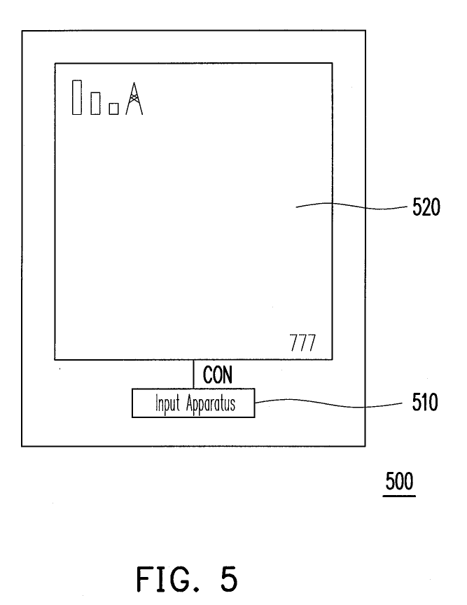

It should be noted that the input apparatuses 100 and 300 can also be used in an electronic apparatus, for improving the convenience of operation of the electronic apparatus. FIG. 5 is a schematic diagram illustrating an electronic apparatus according to an embodiment of the present invention. Referring to FIG. 5, the electronic apparatus 500 includes an input apparatus 510, and a display apparatus 520. The input apparatus 510 for example is either the input apparatus 100 of FIG. 1, or the input apparatus 300 of FIG. 3. When the input apparatus 510 processes the input signals generated by the multi-direction operations, it generates a control signal CON corresponding to a character, and provides the control signal CON to the display apparatus 520. The display apparatus 520 displays the character. The input apparatus 510 is provided with a directional key only for the user to input characters. As such, the space of the electronic apparatus 500 occupied by keys can be saved.

In summary, the foregoing embodiments execute multi-direction operations and successively generate input signals. The successively generated input signals are processed for generating a control signal corresponding to one of a plurality of characters. Therefore, the input apparatus is provided with a direction-indicating key for inputting characters by executing multi-direction operations, thus improving the convenience of operation of the input apparatus. In such a way, when employed in an electronic apparatus, the input apparatus is further adapted for reducing the size of the electronic apparatus using the input apparatus.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An input apparatus, comprising:
a signal generating module, for generating a plurality of input signals by executing multi-direction operations; and
a processing module, receiving and processing successively generated two of the input signals, and generating a control signal, wherein the control signal corresponds to one of a plurality of characters.

2. The input apparatus according to claim 1, wherein the signal generating module comprises:
a first input key, indicating a first direction, for generating a first input signal of the input signals when receiving a first operation instruction;
a second input key, indicating a second direction, for generating a second input signal of the input signals when receiving a second operation instruction;
a third input key, indicating a third direction, for generating a third input signal of the input signals when receiving a third operation instruction; and
a fourth input key, indicating a fourth direction, for generating a fourth input signal of the input signals when receiving a fourth operation instruction.

3. The input apparatus according to claim 2, wherein the signal generating module further comprises:
a fifth input key, for generating a fifth input signal of the input signals when receiving a fifth operation instruction, for controlling the processing module to execute processing or terminate processing.

4. The input apparatus according to claim 2, wherein the signal generating module further comprises:
a fifth input key, for generating a fifth input signal of the input signals when receiving a fifth operation instruction, for switching from the character corresponding to the control signal to another one of the plurality of characters.

5. The input apparatus according to claim 1, wherein the signal generating module further comprises:
a multi-direction key, indicating a first direction, a second direction, a third direction, and a fourth direction, wherein when receiving a first operation instruction, a second operation instruction, a third operation instruction, and a fourth operation instruction, the multi-direction key correspondingly generates a first input signal, a second input signal, a third input signal, and a fourth input signal of the input signals, respectively.

6. The input apparatus according to claim 5, wherein when receiving a fifth operation instruction, the multi-direction key generates a fifth input signal of the input signals for controlling the processing module to execute processing or terminate processing.

7. The input apparatus according to claim 1, wherein the characters comprise Arabic numerals 0 through 9.

8. The input apparatus according to claim 1, wherein the characters comprise English letters A through Z.

9. An input method, adapted for an electronic apparatus, comprising:
providing a signal generating module, wherein the signal generating module generates a plurality of input signals by executing multi-direction operations; and
processing successively generated two of the input signals, for generating a first signal, wherein the first signal corresponds to one of a plurality of characters.

10. The input method according to claim 9, further comprising:
generating a first input signal of the input signals when the signal generating module receives a first operation instruction, wherein the first input signal corresponds to a first direction;
generating a second input signal of the input signals when the signal generating module receives a second operation instruction, wherein the second input signal corresponds to a second direction;
generating a third input signal of the input signals when the signal generating module receives a third operation instruction, wherein the third input signal corresponds to a third direction; and
generating a fourth input signal of the input signals when the signal generating module receives a fourth operation instruction, wherein the fourth input signal corresponds to a fourth direction.

11. The input method according to claim 10, further comprising:
generating a fifth input signal of the input signals when the signal generating module receives a fifth operation instruction, for executing or terminating the step of processing successively generated two of the input signals.

12. The input method according to claim 10, further comprising:
generating a fifth input signal of the input signals when the signal generating module receives a fifth operation instruction, for switching from the character corresponding to the first signal to another one of the plurality of characters.

13. The input method according to claim 9, wherein the characters comprise Arabic numerals 0 through 9.

14. The input method according to claim 9, wherein the characters comprise English letters A through Z.

15. An electronic apparatus, comprising:
an input apparatus, comprising:
a signal generating module, for generating a plurality of input signals by executing multi-direction operations; and
a processing module, receiving and processing successively generated two of the input signals, and generating a control signal, wherein the control signal corresponds to one of a plurality of characters; and
a display apparatus, receiving the control signal, and displaying the one of the plurality of characters.

16. The electronic apparatus according to claim 15, wherein the signal generating module comprises:
a first input key, indicating a first direction, for generating a first input signal of the input signals when receiving a first operation instruction;
a second input key, indicating a second direction, for generating a second input signal of the input signals when receiving a second operation instruction;
a third input key, indicating a third direction, for generating a third input signal of the input signals when receiving a third operation instruction; and
a fourth input key, indicating a fourth direction, for generating a fourth input signal of the input signals when receiving a fourth operation instruction.

17. The electronic apparatus according to claim 16, wherein the signal generating module further comprises:
a fifth input key, for generating a fifth input signal of the input signals when receiving a fifth operation instruction, for controlling the processing module to execute processing or terminate processing.

18. The electronic apparatus according to claim 16, wherein the signal generating module further comprises:
a fifth input key, for generating a fifth input signal of the input signals when receiving a fifth operation instruction, for switching from the character corresponding to the control signal to another one of the plurality of characters.

19. The electronic apparatus according to claim 15, wherein the signal generating module further comprises:
a multi-direction key, indicating a first direction, a second direction, a third direction, and a fourth direction, wherein when receiving a first operation instruction, a second operation instruction, a third operation instruction, and a fourth operation instruction, the multi-direction key correspondingly generates a first input signal, a second input signal, a third input signal, and a fourth input signal of the input signals, respectively.

20. The electronic apparatus according to claim 19, wherein when receiving a fifth operation instruction, the multi-direction key generates a fifth input signal of the input signals for controlling the processing module to execute processing or terminate processing.
